(19) United States
(12) Patent Application Publication
(10) Pub. No.: US 2025/0301655 A1
(43) Pub. Date: Sep. 25, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Sejie Takaki, Suwon-si (KR); Hyeongjin Kim, Suwon-si (KR); Kyungeun Park, Suwon-si (KR); Jeongyong Sung, Suwon-si (KR); Minsoo Shin, Suwon-si (KR); Seungjun Shin, Suwon-si (KR); Joongshik Shin, Suwon-si (KR); Hyeji Lee, Suwon-si (KR); Sunghee Chung, Suwon-si (KR); Woongrae Jo, Suwon-si (KR); Jeehoon Han, Suwon-si (KR)

(21) Appl. No.: 18/952,305

(22) Filed: Nov. 19, 2024

(30) Foreign Application Priority Data
Mar. 19, 2024 (KR) 10-2024-0037777

(51) Int. Cl. H10B 43/40; H10B 41/10; H10B 41/27; H10B 41/35; H10B 41/41; H10B 43/10; H10B 43/27; H10B 43/35

(52) U.S. Cl. CPC H10B 43/40; H10B 41/10; H10B 41/27; H10B 41/35; H10B 41/41; H10B 43/10; H10B 43/27; H10B 43/35

(57) ABSTRACT

A semiconductor device includes: a semiconductor structure on the first semiconductor structure and having first and second regions, wherein the semiconductor structure includes: a plate layer; gate electrodes stacked on the plate layer; interlayer insulating layers alternately arranged with the gate electrodes; a channel structure and the interlayer insulating layers in the first region; and contact plugs penetrating through the pad region of each of the gate electrodes in the second region; and contact insulating layers alternately arranged with the interlayer insulating layers in a lower portion of each of pad regions and configured to surround the contact plugs, wherein each of the contact plugs may include a vertical extension portion and a horizontal extension portion extending from the vertical extension portion and contacting the pad portion, and wherein a width of the horizontal extension portion of the contact plugs may be greater than a width of each of the contact insulating layers.

### CROSS-REFERENCE TO RELATED APPLICATION

This application claims benefit of priority to Korean Patent Application No. 10-2024-0037777 filed on Mar. 19, 2024, in the Korean Intellectual Property Office, the disclosure of which is incorporated herein by reference in its entirety.

### BACKGROUND

The present disclosure relates to semiconductor devices and data storage systems including the same.

In a data storage system requiring data storage, a semiconductor device capable of storing high-capacitance data may be used. Accordingly, research has been conducted into ways to increase the data storage capacitance of semiconductor devices. For example, to increase the data storage capacitance of a semiconductor device, a semiconductor device including memory cells arranged three-dimensionally instead of memory cells arranged two-dimensionally has been proposed. As the process operations for forming the three-dimensionally arranged memory cells become relatively complex, measures to increase process efficiency and ensure reliability have also been researched.

### SUMMARY

An aspect of the present disclosure is to provide semiconductor devices having improved reliability and data storage systems including the same.

However, aspects of the present disclosure are not limited to the above-described aspect, and may be variously extended without departing from the spirit and domain of the present disclosure.

A semiconductor device according to example embodiments of the present disclosure may include: a first semiconductor structure including a substrate, circuit elements on the substrate, and circuit interconnections on the circuit elements; and a second semiconductor structure on the first semiconductor structure and having first and second regions; wherein the second semiconductor structure may include: a plate layer; gate electrodes stacked on the plate layer and spaced apart from each other in a direction, perpendicular to an upper surface of the plate layer, and extending by different lengths in a first direction, intersecting the perpendicular direction, on the second region, each of which includes a pad region in which an upper surface thereof is at least partially exposed, interlayer insulating layers alternately arranged with the gate electrodes; a channel structure extending through the gate electrodes and the interlayer insulating layers in the first region and extending in the perpendicular direction; and contact plugs extending through the pad region of each of the gate electrodes in the second region, extending in the perpendicular direction, and electrically connecting the gate electrodes to a portion of the circuit interconnections, respectively; and contact insulating layers alternately arranged with the interlayer insulating layers in a lower portion of each of pad regions and configured to surround the contact plugs in a plan view of the semiconductor device, wherein each of the contact plugs may include a vertical extension portion extending in the perpendicular direction and a horizontal extension portion extending from the vertical extension portion in the first direction and contacting the pad portion, and wherein a width of the horizontal extension portion of the contact plugs in the first direction may be greater than a width of each of the contact insulating layers in the first direction.

A semiconductor device according to example embodiments of the present disclosure may include: a stack pattern having a memory cell array region and a stepwise region; a stack structure extending from the memory cell array region onto the stepwise region on the stack pattern, wherein the stack structure includes interlayer insulating layers and gate electrodes arranged alternately in a first direction, and the gate electrodes include gate pads arranged in a stepwise shape on the stepwise region, a channel structure extending through the stack structure in the memory cell array region and extending in the first direction; contact plugs extending through the gate electrodes and the interlayer insulating layers in the stepwise region; and contact insulating layers arranged alternately with the interlayer insulating layers between the gate pads and the stack pattern and configured to surround the contact plugs in a plan view of the semiconductor device, wherein each of the contact plugs may include a vertical extension portion extending in the first direction and a horizontal extension portion extending in a second direction from the vertical extension portion perpendicular to the first direction and contacting the gate pads, and wherein the semiconductor device may further include first blocking patterns extending from a space between the gate pads and the interlayer insulating layers to a space between the horizontal extension portion and the interlayer insulating layers.

A data storage system according to example embodiments of the present disclosure may include: a semiconductor storage device including a first semiconductor structure including circuit elements and circuit interconnections electrically connected to the circuit elements, a second semiconductor structure on one surface of the first semiconductor structure and including a first region and a second region, and an input/output pad electrically connected to the circuit elements; and a controller electrically connected to the semiconductor storage device through the input/output pad and configured to control the semiconductor storage device, wherein the second semiconductor structure may include: a plate layer; gate electrodes stacked on the plate layer and spaced apart from each other in a direction, perpendicular to an upper surface of the plate layer, and extending by different lengths in a first direction, intersecting the perpendicular direction, on the second region, each of which includes a pad region in which an upper surface thereof is at least partially exposed; interlayer insulating layers alternately arranged with the gate electrodes; a channel structure extending through the gate electrodes and the interlayer insulating layers in the first region and extending in the perpendicular direction; contact plugs extending through the pad region of each of the gate electrodes in the second region, extending in the perpendicular direction, and electrically connecting the gate electrodes to a portion of the circuit interconnections, respectively; and contact insulating layers alternately arranged with the interlayer insulating layers in a lower portion of each of pad regions and configured to surround the contact plugs in a plan view of the semiconductor device, wherein each of the contact plugs may include a vertical extension portion extending in the perpendicular direction and a horizontal extension portion extending from the vertical extension portion in a the first direction and contacting the pad region, and wherein first blocking patterns are between the horizontal extension portion and the interlayer insulating layers and second blocking patterns are between the contact insulating layers and the interlayer insulating layers.

Semiconductor devices and data storage systems including the same according to example embodiments of the present disclosure may include blocking patterns disposed between a horizontal extension portion of a contact plug and interlayer insulating layers and between contact insulating layers and interlayer insulating layers. Accordingly, the durability of the interlayer insulating layers may be secured, thereby providing a semiconductor device with improved reliability and a data storage system including the same.

Advantages and effects of the present application are not limited to the foregoing content and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments of the present disclosure;

FIG. 2 is a cross-sectional view taken along line I-I′ of the semiconductor device of FIG. 1 according to an example embodiment;

FIG. 3 is a cross-sectional view illustrating taken along line II-II′ of the semiconductor device of FIG. 1 according to an example embodiment;

FIG. 4 is a schematic enlarged view of region A of the semiconductor device of FIG. 2;

FIG. 5A is an enlarged view illustrating an example embodiment of region B of the semiconductor device of FIG. 4;

FIG. 5B is an enlarged view illustrating another example embodiment of region B of the semiconductor device of FIG. 4;

FIG. 5C is an enlarged view illustrating another embodiment of region B of the semiconductor device of FIG. 4;

FIGS. 6 to 15 are cross-sectional views illustrating an embodiment of a method of manufacturing the semiconductor device of FIG. 1;

FIG. 16 is a cross-sectional view taken along line I-I′ of the semiconductor device of FIG. 1 according to another example embodiment; and

FIG. 17 is a view schematically illustrating a data storage system including a semiconductor device according to example embodiments of the present disclosure.

### DETAILED DESCRIPTION

Hereinafter, example embodiments of the present disclosure will be described with reference to the accompanying drawings. The same reference numerals are used for the same components in the drawings, and duplicate descriptions of the same components are omitted. As used herein, the term “and/or” includes any and all combinations of one or more of the associated listed items. It will be understood that, although the terms “first,” “second,” “upper portion,” “lower portion,” etc. may be used herein to describe various elements or components, these elements or components should not be limited by these terms. These terms are only used to distinguish one element or component from another element or component. Therefore, a first element or component discussed below could be termed a second element or component. It is noted that aspects described with respect to one embodiment may be incorporated in different embodiments although not specifically described relative thereto. That is, all embodiments and/or features of any embodiments can be combined in any way and/or combination.

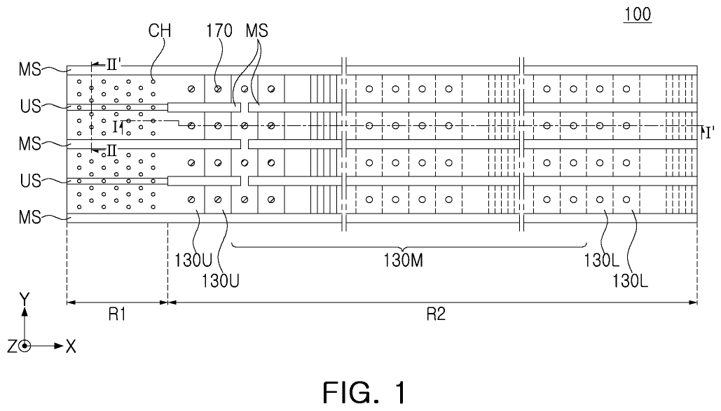

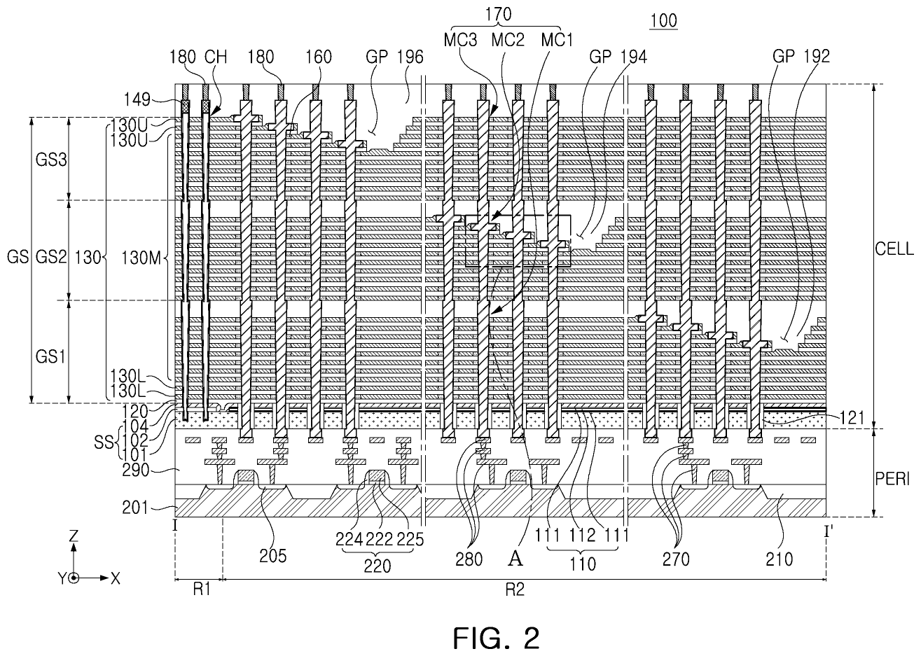

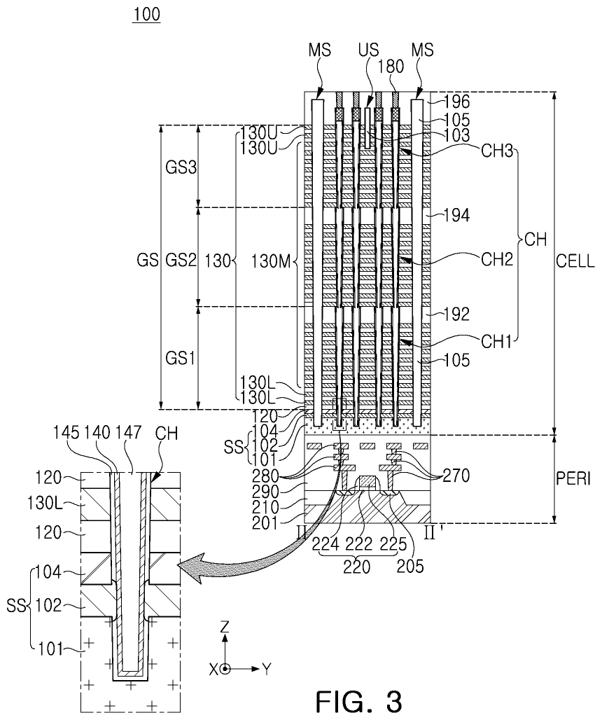

FIG. 1 is a schematic plan view of a semiconductor device according to example embodiments of the present disclosure. FIG. 2 is a cross-sectional view taken along line I-I′ of the semiconductor device of FIG. 1 according to an example embodiment. FIG. 3 is a cross-sectional view illustrating taken along line II-II′ of the semiconductor device of FIG. 1 according to an example embodiment.

Referring to FIGS. 1 to 3, a semiconductor device 100 may include a peripheral circuit region PERI, a first semiconductor structure including a substrate 201, and a memory cell region CELL, a second semiconductor structure including a plate layer 101. The memory cell region CELL may be disposed on the peripheral circuit region PERI. In another example, the memory cell region CELL may be disposed below (in the Z-direction) the peripheral circuit region PERI.

The peripheral circuit region PERI may include the substrate 201, impurity regions 205 within the substrate 201, device isolation layers 210, circuit elements 220 disposed on the substrate 201, a peripheral region insulating layer 290, a circuit contact plug 270, and circuit interconnection lines 280.

The substrate 201 may have an upper surface extending in a first direction (X-direction) and a second direction (Y-direction). An active region may be defined on the substrate 201 by the device isolation layers 210. The impurity regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include planar transistors. Each of the circuit elements 220 may include a circuit gate dielectric layer 222, a spacer layer 224, and a circuit gate electrode 225. The impurity regions 205 may be disposed as source/drain regions in the substrate 201 on both sides of the circuit gate electrode 225.

The peripheral region insulating layer 290 may be disposed on the circuit element 220 on the substrate 201. The peripheral region insulating layer 290 may include a plurality of insulating layers formed in different process operations. The peripheral region insulating layer 290 may be formed of an insulating material.

The circuit contact plugs 270 and the circuit interconnection lines 280 may be included in a circuit interconnection structure electrically connected to the circuit elements 220 and the impurity regions 205. The circuit contact plugs 270 may have a cylindrical shape, and the circuit interconnection lines 280 may have a line shape. An electrical signal may be applied to the circuit element 220 through the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, may have a line shape, and may be arranged in a plurality of layers. The circuit contact plugs 270 and the circuit interconnection lines 280 may include a conductive material, and may include, for example, tungsten (W), copper (Cu), aluminum (Al), and each of the components may further include a diffusion barrier. In example embodiments, the number of layers of the circuit contact plugs 270 and the circuit interconnection lines 280 may be variously changed.

The memory cell region CELL may include a first region R1 and a second region R2. The memory cell region CELL may include a source structure SS including a plate layer 101, gate electrodes 130 stacked on the source structure SS and included in a gate structure GS, interlayer insulating layers 120 alternately stacked with the gate electrodes 130 and included in the gate structure GS, channel structures CH disposed to penetrate or extend through the gate structure GS in the first region R1, first separation regions MS extending by penetrating or extending through the gate structure GS, second separation regions US penetrating or extending through a portion of the gate electrodes 130 disposed on an upper portion, and contact plugs 170 connected to the gate electrodes 130 and extending vertically in the second region R2. In an example, the memory cell region CELL may further include a horizontal insulating layer 110 disposed below (in the Z-direction) the gate electrodes 130 in the second region R2, substrate insulating layers 121 disposed to penetrate or extend through the plate layer 101, a channel structure CH and studs 180 on the contact plugs 170, and first to third cell region insulating layers 192, 194 and 196 configured to be on and at least partially cover the gate electrodes 130.

In the memory cell region CELL, the first region R1 is a region in which the gate electrodes 130 are vertically (in the Z-direction) stacked and the channel structure CH is disposed, and may be a region in which memory cells are disposed. The second region R2 is a region in which the gate electrodes 130 extend by different lengths in the X-direction to form gate pad regions GP, and may be a region for electrically connecting the memory cells to the peripheral circuit region PERI. The second region R2 may be disposed on at least one end of the first region R1 in at least one direction, for example, a first direction (X-direction). In this document, the first region R1 may be referred to as a memory cell array region, and the second region R2 may be referred to as a stepwise region.

The source structure SS may include the plate layer 101, a first horizontal conductive layer 102, and a second horizontal conductive layer 104 sequentially stacked in the first region R1. However, in example embodiments, the number of conductive layers included in the source structure SS may be variously changed. In this document, the source structure SS may be referred to as a stack pattern.

The plate layer 101 may have a shape of a plate, and may function as at least a portion of the common source line of the semiconductor device 100. The plate layer 101 may have an upper surface extending in the first direction (X-direction) and the second direction (Y-direction). The plate layer 101 may include a conductive material. For example, the plate layer 101 may include a semiconductor material, such as a group IV semiconductor, a group III-V compound semiconductor, and/or a group II-VI compound semiconductor. For example, the group IV semiconductors may include silicon, germanium, or silicon-germanium. The plate layer 101 may further include impurities. The plate layer 101 may be provided as a polycrystalline semiconductor layer, such as a polycrystalline silicon layer or an epitaxial layer.

The first and second horizontal conductive layers 102 and 104 may be sequentially stacked and disposed on an upper surface of the plate layer 101 in the first region R1. The first horizontal conductive layer 102 does not extend into the second region R2, and the second horizontal conductive layer 104 may extend into the second region R2. The first horizontal conductive layer 102 may function as a portion of a common source line of the semiconductor device 100, and may function as, for example, a common source line with plate layer 101. As illustrated in FIG. 3, the first horizontal conductive layer 102 may be directly connected to the channel layer 140 around the channel layer 140. The second horizontal conductive layer 104 may be in contact with the plate layer 101 in some regions of the second region R2 in which the first horizontal conductive layer 102 and the horizontal insulating layer 110 are not disposed.

The first and second horizontal conductive layers 102 and 104 may include a semiconductor material, for example, polycrystalline silicon. In this case, at least the first horizontal conductive layer 102 may be a layer doped with impurities of the same conductivity type as the plate layer 101, and the second horizontal conductive layer 104 may be a doped layer or a layer including impurities diffused from the first horizontal conductive layer 102. However, the material of the second horizontal conductive layer 104 is not limited to a semiconductor material, and may be replaced with an insulating layer.

The horizontal insulating layer 110 may be disposed on the plate layer 101 on the same level (in the Z-direction) as the first horizontal conductive layer 102 in at least a portion of the second region R2. The horizontal insulating layer 110 may include first and second horizontal insulating layers 111 and 112 alternately stacked on the second region R2 of the plate layer 101. The horizontal insulating layer 110 may be layers remaining after a portion of the horizontal insulating layer 110 is replaced with the first horizontal conductive layer 102 during a manufacturing process of the semiconductor device 100.

The horizontal insulating layer 110 may include silicon oxide, silicon nitride, silicon carbide, and/or silicon oxynitride. The first horizontal insulating layer 111 and the second horizontal insulating layer 112 may include different insulating materials. For example, the first horizontal insulating layers 111 may be formed of the same material as the interlayer insulating layers 120, and the second horizontal insulating layer 112 may be formed of a material different from the interlayer insulating layers 120.

The substrate insulating layers 121 may be disposed to penetrate or extend through the plate layer 101, the horizontal insulating layer 110, and the second horizontal conductive layer 104 in a portion of the second region R2. The substrate insulating layers 121 may be further disposed in the first region R1, and may be disposed, for example, in a region in which a through-via extending from the memory cell region CELL to the peripheral circuit region PERI is disposed. An upper surface of the substrate insulating layer 121 may be coplanar with an upper surface of the second horizontal conductive layer 104. The substrate insulating layer 121 may include an insulating material, for example, silicon oxide, silicon nitride, silicon carbide, and/or silicon oxynitride.

The gate electrodes 130 may be spaced apart from each other vertically (Z-direction) and stacked on the plate layer 101, and may thus be included in a gate structure GS together with the interlayer insulating layers 120. The gate structure GS may include first, second and third stack structures GS1, GS2 and GS3, which are vertically (Z-direction) stacked. However, according to example embodiments, the number of stack structures of the gate structure GS may be variously changed. For example, the gate structure GS may be comprised of four or more stack structures, and may be comprised of a single stack structure or two stack structures. The number of gate electrodes 130 of each of the first, second and third stack structures GS1, GS2 and GS3 may be identical to or different from each other.

The gate electrodes 130 may comprise lower gate electrodes 130L included in a gate of a ground selection transistor, memory gate electrodes 130M included in a plurality of memory cells, and upper gate electrodes 130U included in gates of string selection transistors. The number of memory gate electrodes 130M included in memory cells may be determined according to the capacitance of the semiconductor device 100. According to an example embodiment, the number of upper and lower gate electrodes 130U and 130L may be one to four or more, respectively, and may have a structure identical to or different from that of the memory gate electrodes 130M. In example embodiments, the gate electrodes 130 may further include gate electrodes 130 disposed adjacently to the upper gate electrodes 130U and/or the lower gate electrodes 130L and included in an erase transistor used in an erase operation using a gate induced leakage current (GIDL) phenomenon. Additionally, some of the gate electrodes 130, for example, the memory gate electrodes 130M adjacent to the upper or lower gate electrodes 130U and 130L, may be dummy gate electrodes.

As illustrated in FIG. 1, the gate electrodes 130 may be separated from each other in the second direction (Y-direction) by first separation regions MS continuously extending from the first region R1 and the second region R2. The gate electrodes 130 between a pair of first separation regions MS may be included in one memory block, and the range of the memory block is not limited thereto. Some of the gate electrodes 130, for example, the memory gate electrodes 130M, may be respectively included in one layer inside the one memory block.

The gate electrodes 130 may be spaced apart from each other vertically (Z-direction) and stacked on the first region R1, and may extend from the first region R1 to the second region R2 by different lengths, thereby forming step structures having a stepwise shape in the gate pad regions GP. The gate pad regions GP may be defined as regions including gate pads connected to the contact plugs 170 of the gate electrodes 130. As illustrated in FIG. 2, the gate electrodes 130 may have a shape in which a predetermined depth is removed from an upper portion of any one of the first to third stack structures GS1, GS2 and GS3 in the gate pad regions GP. The gate pad regions GP may be arranged so as not to overlap each other in a third direction (Z-direction), a vertical direction. The gate electrodes 130 included in the second and third stack structures GS2 and GS3 may extend horizontally on the gate pad regions GP of the first and second stack structures GS1 and GS2 in a lower portion. In an example embodiment, the gate pad regions GP may be arranged in order from the first region R1 to the third stack structure GS3, the second stack structure GS2, and the first stack structure GS1 in the first direction (X-direction). Only one gate pad region GP is illustrated in each of the first, second and third gate stack structures GS1, GS2 and GS3, but a plurality of gate pad regions GP may be disposed in each of the first, second and third gate stack structures GS1, GS2 and GS3. However, in example embodiments, the arrangement form, arrangement order, and depth of the gate pad region GP may be variously changed. In an example, the gate electrodes 130 may not be disposed on the gate pad regions GP.

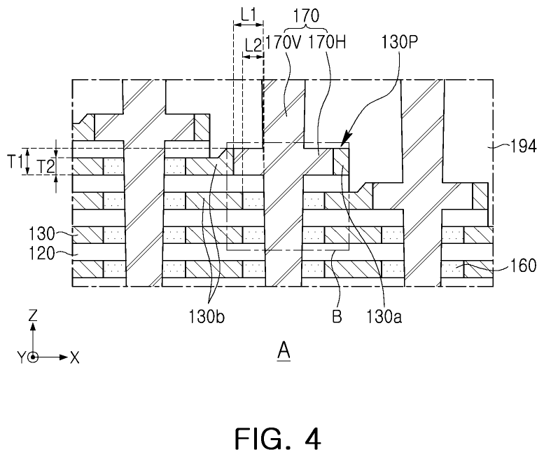

The gate electrodes 130 may form first and second step structures in an asymmetrical form in the first direction (X-direction) in each of gate pad regions GP. The first step structure may be disposed relatively adjacently to the first region R1 and may be a stepwise structure in which a level thereof decreases in the first direction (X-direction), and the second step structure may be disposed to be relatively far from the first region R1 and may be a stepwise structure in which a level thereof increases in the first direction (X-direction). For example, an inclination of the first step structure in each of the gate pad regions GP may be smaller than an inclination of the second step structure in the first region R1. However, in some example embodiments, the first and second step structures may have symmetrical shapes. The gate electrodes 130 are connected to the contact plugs 170 in the first step structure, and the gate electrodes 130 may form a dummy region or a dummy structure that is not connected to the contact plugs 170 in the second step structure. In example embodiments, a specific shape of the step structure, and the number of gate electrodes 130 of each of the step structures are not limited to the form illustrated in FIG. 2. In some example embodiments, the gate electrodes 130 may be arranged to have a step structure in the second direction (Y-direction). The gate electrodes 130 may include contact regions (e.g., contact regions 130P in FIG. 4) connected to the contact plugs 170. The contact regions may be defined as one region of the gate electrode layer that is not covered by other gate electrodes in one stack structure, that is, a region in which gate pads in contact with peripheral contact plug 170 are disposed in each of the stack structures GS disposed in the second region R2.

The gate electrodes 130 may include a metal material, for example, tungsten (W). According to an example embodiment, the gate electrodes 130 may include polycrystalline silicon or metal silicide material. In example embodiments, the gate electrodes 130 may further include a diffusion barrier, and the diffusion barrier may include, for example, tungsten nitride (WN), tantalum nitride (TaN), titanium nitride (TiN), or combinations thereof.

The interlayer insulating layers 120 may be disposed between the gate electrodes 130. Similar to the gate electrodes 130, the interlayer insulating layers 120 may be spaced apart from each other in a direction, perpendicular to the upper surface of the plate layer 101 and may extend in the first direction (X-direction). In each of the first, second, and third stack structures GS1, GS2, and GS3, a thickness of the interlayer insulating layers 120 may not be the same. In an example, at least some of the interlayer insulating layers 120 may have different thicknesses. Additionally, the number of interlayer insulating layers 120 may be variously changed from that illustrated. The interlayer insulating layers 120 may include an insulating material, such as silicon oxide or silicon nitride.

The channel structures CH may be in included in each of the memory cell strings, and may be spaced apart from each other in rows and columns on the plate layer 101 in the first region R1. The channel structures CH may be disposed to have a grid pattern on an X-Y plane, or may be disposed in a zigzag shape in one direction. The channel structures CH may have a pillar shape and may have an inclined side surface that becomes narrower as the channel structures CH approach the plate layer 101 depending on an aspect ratio. According to an example embodiment, at least some of the channel structures CH disposed in an end of the first region R1 may be dummy channel structures.

Referring to FIG. 3, each of the channel structures CH may include first, second and third channel portions CH1, CH2 and CH3 stacked in a vertical direction (Z-direction). The first, second and third channel portions CH1, CH2, and CH3 may respectively penetrate or extend through the first, second and third stack structures GS1, GS2 and GS3 of the gate structure GS. The channel structure CH may have a form in which the first channel portion CH1, the second channel portion CH2 on an upper portion of the first channel portion CH1, and a third channel portion CH3 on an upper portion of the second channel portion CH2 are connected. The first, second and third channel units CH1, CH2 and CH3 may have a shape in which a width of an upper surface of the channel portion disposed in a lower portion is larger than a width of a lower surface of the channel portion disposed in an upper portion in a region or an interface in which first, second and third channel units CH1, CH2 and CH3 are connected to each other. The channel structure CH may have bent portions due to differences in width in the interface between the first, second and third channel portions CH1, CH2 and CH3. However, according to example embodiments, the number of channel portions stacked in the third direction (Z-direction) in the channel structure CH may be variously changed. The first channel portion CH1 may further penetrate or extend through the source structure SS, and a lower end of the first channel portion CH1 may be disposed in the plate layer 101.

Each of the channel structures CH may include a channel layer 140 disposed in a channel hole, a gate dielectric layer 145, a channel buried insulating layer 147, and a channel pad 149. The channel layer 140, the gate dielectric layer 145, and the channel buried insulating layer 147 may be connected to each other between the first, second, and third channel portions CH1, CH2 and CH3.

The channel layer 140 may be formed to have an annular shape surrounding the channel buried insulating layer 147 inside, but according to an example embodiment, the channel layer 140 may have a pillar shape such as a cylinder or a prism without the channel buried insulating layer 147. The channel layer 140 may be connected to a first horizontal conductive layer 102 in the lower portion. The channel layer 140 may include a semiconductor material such as polycrystalline silicon or single crystalline silicon.

The gate dielectric layer 145 may be disposed between the gate electrodes 130 and the channel layer 140. Although not specifically illustrated, the gate dielectric layer 145 may include a tunneling layer, a charge storage layer, and a blocking layer sequentially stacked from the channel layer 140. The tunneling layer may tunnel charges into the charge storage layer, and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-K dielectric material, or combinations thereof. In example embodiments, at least a portion of gate dielectric layer 145 may extend in a horizontal direction along the gate electrodes 130.

The channel pad 149 may be disposed only in an upper end of the third channel portion CH3 in the upper portion. The channel pad 149 may include, for example, doped polycrystalline silicon.

The first separation regions MS may be arranged to extend in the first direction (X-direction) by penetrating or extending through at least a portion of the gate electrodes 130. As illustrated in FIG. 1, the first separation regions MS may be arranged in parallel with each other. A portion of the separation regions MS may extend as one along the first region R1 and the second region R2 and the remainder thereof may extend only to a portion of the second region R2, or may be disposed intermittently in the first region R1 and the second region R2. However, in example embodiments, the arrangement form and number of the first separation regions MS are not limited to those illustrated in FIG. 1.

The first separation regions MS may penetrate or extend through the gate electrodes 130 stacked on the plate layer 101, and may be connected to the plate layer 101 by further penetrating or extending through the first and second horizontal conductive layers 102 and 104 below. The first separation regions MS may have a shape of which a width thereof decreases toward the plate layer 101 due to a high aspect ratio. For example, a side surface of the first separation regions MS may have a side surface of a substantially constant slope such that a width thereof continuously or consecutively decreases, and the first separation regions MS may not have bent portions on the side surface thereof.

A gate isolation insulating layer 105 may be disposed in each of the first separation regions MS. The gate isolation insulating layer 105 may include an insulating material, may include, for example, silicon oxide, silicon nitride, or silicon oxynitride.

Referring to FIGS. 1 and 3, the second separation regions US may extend in the first direction (X-direction) between adjacent first separation regions MS. The second separation regions US may be disposed in a portion of the second region R2 and the first region R1. The second separation regions US may penetrate or extend through some of the gate electrodes 130 including an upper gate electrode 130U in an uppermost portion, among the gate electrodes 130. For example, the second separation regions US may separate a total of three gate electrodes 130 from each other in the second direction (Y-direction). However, the number of gate electrodes 130 separated by the second separation regions US may be variously changed according to example embodiments.

Each of the second separation regions US may include an upper separation insulating layer 103. The upper separation insulating layer 103 may include an insulating material, and may include, for example, silicon oxide, silicon nitride, and/or silicon oxynitride.

The contact plugs 170 may be connected to the contact regions 130P of the gate electrodes 130 in the gate pad regions GP in the second region R2. The contact plugs 170 may penetrate through at least a portion of the cell region insulating layers 192, 194 and 196, and may be connected to each of the contact regions 130P of the gate electrodes 130 exposed upwardly. The contact plugs 170 may penetrate or extend through the gate electrodes 130 above and below (in the Z-direction) the contact regions 130P, and may penetrate or extend through the second horizontal conductive layer 104, the horizontal insulating layer 110, and the plate layer 101 and may be connected to the circuit interconnection lines 280 in the peripheral circuit region PERI. The contact plugs 170 may be spaced apart from the gate electrodes 130 above and below (in the Z-direction) the contact regions 130P by contact insulating layers 160. The contact plugs 170 may be spaced apart from the plate layer 101, the horizontal insulating layer 110, and the second horizontal conductive layer 104 by the substrate insulating layers 121.

The contact plugs 170 may have a shape corresponding to the channel structures CH. Each of the contact plugs 170 may include first to third contact portions MC1, MC2 and MC3 stacked from the lower portion. The first, second and third contact portions MC1, MC2 and MC3 may penetrate or extend through the first, second and third stack structures GS1, GS2 and GS3 of the gate structure GS, respectively. The first contact portion MC1 may further penetrate or extend through the substrate insulating layer 121. The first to third contact portions MC1, MC2 and MC3 may have a cylindrical shape in which a width thereof decreases toward the substrate 201 due to the aspect ratio. Each of the first to third contact portions MC1, MC2 and MC3 may have a substantially constant slope. The first contact portion MC1 may further include a landing region in which a width thereof is expanded below (in the Z-direction) the substrate insulating layer 121. However, in some example embodiments, the first contact portion MC1 may not include the landing region.

The first, second and third contact portions MC1, MC2 and MC3 have a shape in which a width of an upper surface of the contact portion disposed in the lower portion is larger than a width of the lower surface of the contact portion disposed in the upper portion in a region or an interface in which the first, second and third contact portions MC1, MC2 and MC3 are connected to each other. Accordingly, similar to the channel structure CH, the contact plug 170 may also have bent portions due to differences in width in the interface between the first, second and third contact portions MC1, MC2 and MC3.

A level of the interface between the first contact portion MC1 and the second contact portion MC2 may be the same as a level of the interface between the first channel portion CH1 and the second channel portion CH2 in the Z-direction. In an example, a level of an upper surface of the first contact portion MC1 may be the same as a level of an upper surface of the first channel portion CH1, and a level of an upper surface of the second contact portion MC2 may be the same as a level of an upper surface of the second channel portion CH2 in the Z-direction.

The contact plugs 170 may include a conductive material, for example, tungsten (W), copper (Cu), and/or aluminum (Al), and alloys thereof. In some example embodiments, the contact plugs 170 may include a barrier layer extending along a side surface and a bottom surface thereof, or may have an air gap therein.

The contact insulating layers 160 may be disposed to surround a side surface of each of the contact plugs 170 above and below the contact regions 130P in a plan view of the semiconductor device 100. The contact insulating layers 160 may be spaced apart from each other in the third direction (Z-direction) around each of the contact plugs 170. The contact insulating layers 160 may extend horizontally (X-direction) from each side surface of the contact plugs 170 by substantially the same length. The contact insulating layers 160 may be disposed on substantially the same level as the gate electrodes 130 in the Z-direction. The contact insulating layers 160 may include an insulating material, and may include, for example, silicon oxide, silicon nitride, and/or silicon oxynitride.

The studs 180 may be included in a cell interconnection structure electrically connected to memory cells in the memory cell region CELL. The studs 180 may be connected to the channel structures CH and the contact plugs 170, and may be electrically connected to the channel structures CH and the gate electrodes 130. The studs 180 are illustrated as having a plug shape, but are not limited thereto and may also have a line shape. In example embodiments, the number of plugs and interconnection lines included in the cell interconnection structure may be variously changed. The studs 180 may include a metal, and may include, for example, tungsten (W), copper (Cu), and/or aluminum (Al).

The first to third cell region insulating layers 192, 194 and 196 may be arranged to be on and at least partially cover the first, second and third stack structures GS1, GS2, and GS3, respectively. The first to third cell region insulating layers 192, 194 and 196 may be disposed on an uppermost portion of the first, second and third stack structures GS1, GS2 and GS3. The first, second and third cell region insulating layers 192, 194 and 196 may be formed of an insulating material, and may be formed of a plurality of insulating layers. When the first, second and third cell region insulating layers 192, 194 and 196 include the same material as the interlayer insulating layers 120, an interface with the interlayer insulating layers 120 may not be distinguished thereby forming a unitary or monolithic structure. The first, second and third cell region insulating layers 192, 194 and 196 and the interlayer insulating layers 120 may be collectively referred to as interlayer insulating layers in this document.

In this document, the first direction (X-direction) and the second direction (Y-direction) may be perpendicular to each other. The first direction (X-direction) and the second direction (Y-direction) may be perpendicular to the third direction (Z-direction). The horizontal direction may refer to the first direction (X-direction) and the second direction (Y-direction).

FIG. 4 is a schematic enlarged view of region A of the semiconductor device of FIG. 2.

Referring to FIG. 4, contact plugs 170 may be electrically connected to one of the gate electrodes 130 through contact regions 130P.

The gate electrodes 130 may include first gate electrode portions 130a corresponding to a contact region 130P and second gate electrode portions 130b in contact with contact insulating layers 160.

The first gate electrode portions 130a are electrode portions in contact with the contact plugs 170, and may extend from the second gate electrode portion 130b in the second region R2 and may be arranged in a stepwise shape. The first gate electrode portions 130a may be in contact with an outer surface of a horizontal extension portion 170H. In this document, the first gate electrode portion 130a may be referred to as gate pads.

The second gate electrode portions 130b are electrode portions in contact with the contact insulating layers 160, and may extend from the first region R1 to the second region R2. In an example, the first gate electrode portion 130a may extend from the second gate electrode portion 130b. In an example, a thickness T1 of the first gate electrode portion 130a may be thicker than a thickness T2 of the first gate electrode portion 130b.

The contact plug 170 may have a shape extending from the contact region 130P in the horizontal direction. In an example, contact plug 170 may include a vertical extension portion 170V extending in the third direction (Z-direction) and a horizontal extension portion 170H extending from the vertical extension portion 170V in the horizontal direction (X-direction) to be in contact with the gate electrode 130. In an example, horizontal extension portion 170H may be disposed along a circumference of the vertical extension portion 170V and an entire side surface thereof may be surrounded by the first gate electrode portion 130a of the gate electrodes 130 in a plan view of the semiconductor device 100. The vertical extension portion 170V extending below the pad region 130P may be surrounded by the contact insulating layers 160 in a plan view of the semiconductor device 100.

A first length L1 from a side surface of the vertical extension portion 170V to an end of the horizontal extension portion 170H may be greater than a second length L2 from the side surface of the vertical extension portion 170V to an outer surface of the contact insulating layer 160. In an example, a width of the horizontal extension portion 170H in the horizontal direction (X-direction) may be greater than a width of the contact insulating layer 160 in the horizontal direction (X-direction). In an example, a portion of the contact plug 170V may not overlap the contact insulating layer 160 in the third direction (Z-direction).

The contact plug 170 may be electrically separated from the gate electrodes 130 below the contact regions 130P, that is, gate electrodes 130 that are not connected to the contact plug 170, by the contact insulating layers 160.

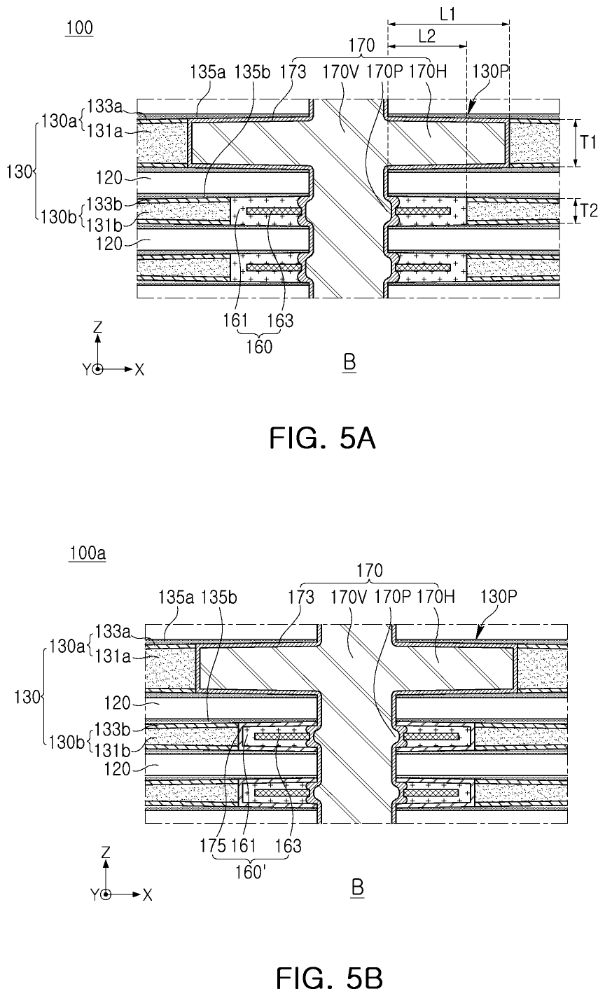

FIG. 5A is an enlarged view illustrating an example embodiment of region B of the semiconductor device of FIG. 4.

Referring to FIG. 5A, a semiconductor device 100 may further include a first blocking pattern 135a disposed between an interlayer insulating layer 120 and a horizontal extension portion 170H of a contact plug 170, and a second blocking pattern 135b disposed between the interlayer insulating layer 120 and contact insulating layers 160.

The interlayer insulating layers 120 and gate electrodes 130 may be alternately arranged in the third direction (Z-direction). The gate electrodes 130 may include a first gate electrode portion 130a in which an upper surface thereof is at least partially exposed upwardly (Z-direction) and connected to the contact plug 170 and a second gate electrode portion 130b disposed below (in the Z-direction) a pad region 130P and in contact with the contact insulating layers 160.

The first gate electrode portion 130a and the second gate electrode portion 130b may include conductive films 131a and 131b and barrier films 133a and 133b disposed on an upper surface and a lower surface of the conductive films 131a and 131b. The conductive film 131a of the first gate electrode portion 130a may be disposed between the barrier films 133a. The conductive film 131b of the second gate electrode portion 130b may be disposed between the barrier films 133b. In an example, the conductive films 131a and 131b may include tungsten (W), copper (Cu), aluminum (Al), and alloys thereof. The barrier films 133a and 133b may include at least one of titanium (Ti), titanium nitride (TiN), tantalum (Ta), and/or tantalum nitride (TaN).

The contact plug 170 may penetrate or extend through the interlayer insulating layers 120 and the gate electrodes 130 in the third direction (Z-direction). In an example, the contact plug 170 may include a vertical extension portion 170V extending in the third direction (Z-direction), a horizontal extension portion 170H extending in the horizontal direction (X-direction) from the vertical extension portion 170V and connected to the first gate electrode portion 130a, and a protrusion portion 170P protruding in the horizontal direction from the vertical extension portion 170V toward the contact insulating layers 160. The contact plug 170 may further include a barrier film 173 at least partially covering the protrusion portion 170P. In an example, the vertical extension portion 170V, the horizontal extension portion 170H, and the protrusion portion 170P may include tungsten (W), copper (Cu), aluminum (Al), and/or alloys thereof. The barrier film 173 may be disposed conformally along a surface profile of the vertical extension portion 170V, the horizontal extension portion 170H, and the protrusion portion 170P. For example, the barrier film 173 may include titanium (Ti), titanium nitride (TiN), tantalum (Ta), and/or tantalum nitride (TaN).

The contact insulating layers 160 may be arranged alternately with the interlayer insulating layers 120 below (Z-direction) the pad region 130P and may surround the vertical extension portion 170V of the contact plug 170 in a plan view of the semiconductor device 100. The contact insulating layers 160 may extend horizontally by substantially the same length from a side surface of the vertical extension portion 170V. The contact insulating layers 160 may be disposed on substantially the same level (in the Z-direction) as the second gate electrode portion 130b. In an example, an internal surface of the contact insulating layers 160 may be in contact with the vertical extension portion 170V of the contact plug 170. In an example, an outer surface of the contact insulating layers 160 may be in contact with the second gate electrode portion 130b. In an example, one surface of the protrusion portion 170P may have a structure corresponding to a surface profile of the internal surface of the contact insulating layers 160. For example, the internal surface of the contact insulating layers 160 may have a concavo-convex structure, and one surface of the protrusion portion 170P may have a concavo-convex structure. However, the present disclosure is not limited thereto, and the internal surface of the contact insulating layers 160 may have a concave portion, and one surface of the protrusion portion 130P may also have a concave portion.

Each of the contact insulating layers 160 may include a first insulating pattern 161 including a first insulating material, and a second insulating pattern 163 disposed on an internal surface of the first insulating pattern 161 and including a second insulating material different from the first insulating material. In an example, the first insulating material may have a lower density than the second insulating material. For example, the first insulating material may include silicon oxide (SiO₂), and the second insulating material may include silicon oxynitride (SiON).

One side surface of the first insulating pattern 161 and one side surface of the second insulating pattern 163 at least partially surrounded by one side surface of the first insulating pattern 161 may be in contact with the protrusion portion 170P of the contact plug 170. An outer surface of the first insulating pattern 161 may be in contact with the second gate electrode portion 130b.

The first blocking patterns 135a may be disposed between the interlayer insulating layers 120 and the horizontal extension portion 170H of the contact plug 170. The first blocking patterns 135a may extend between the interlayer insulating layer 120 and the first gate electrode portion 130a in the horizontal direction (X-direction). In an example, the second blocking patterns 135b may be disposed between the interlayer insulating layers 120 and the contact insulating layer 160. The second blocking patterns 135b may extend between the interlayer insulating layers 120 and the second gate electrode portion 130b. In an example, the first and second blocking patterns 135a and 135b may be disposed between the interlayer insulating layers 120. The first and second blocking patterns 135a and 135b may not extend in the third direction (Z-direction). That is, the first and second blocking patterns 135a and 135b do not extend on a side surface of the interlayer insulating layers 120 in the horizontal direction (X-direction).

The first and second blocking patterns 135a and 135b may include metal oxide. For example, the first and second blocking patterns 135a and 135b may include aluminum oxide (AlO).

A thickness of the first and second blocking patterns 135a and 135b may decrease as the first and second blocking patterns 135a and 135b approach the vertical extension portion 170V. In an example, a distance in the third direction (Z-direction) between the first blocking patterns 135a may be greater than a distance in the third direction (Z-direction) between the second blocking patterns 135b.

A semiconductor device according to example embodiments may include a contact plug 170 including a horizontal extension portion 170H connected to the contact region 130P of the gate electrode 130, and contact insulating layers 160 alternating with interlayer insulating layers 120 below the contact region 130P and surrounding the contact plug 170 in a plan view of the semiconductor device. Additionally, the semiconductor device may include a first blocking pattern 135a disposed between the horizontal extension portion 170H and the interlayer insulating layers 120, and a second blocking pattern 135b disposed between the contact insulating layer 160 and the interlayer insulating layers 120, thereby reducing the likelihood of or preventing the interlayer insulating layers 120 from being damaged during the manufacturing process of the semiconductor device. Accordingly, a semiconductor device with improved reliability may be provided.

FIG. 5B is an enlarged view illustrating another example embodiment of region B of the semiconductor device of FIG. 4.

Among the remaining components excluding contact insulating layers 160′ illustrated in FIG. 5B, overlapping descriptions of components that are identical to or correspond to those illustrated in FIG. 5A will be omitted.

Referring to FIG. 5B, a semiconductor device 100a may include the contact insulating layers 160′ surrounding the contact plug 170 below the contact region 130P in a plan view of the semiconductor device. Each of the contact insulation layers 160′ may include a first insulating pattern 161 including a first insulating material, a second insulating pattern 163 disposed on an internal surface of the first insulating pattern 161 and including a second insulating material different from the first insulating material, and an insulating liner 175 including a third insulating material different from the first insulating material and on and at least partially covering an outer surface of the first insulating pattern 161. In an example, a thickness of the insulating liner 175 may be less than the thickness of the first insulating pattern 161. In an example, the first insulating material may have a lower density than the second insulating material and the third insulating material. In an example, the third insulating material may be the same as the second insulating material. For example, the first insulating material includes silicon oxide (SiO₂), and the second and third insulating materials may include silicon oxynitride (SiON).

The insulating liner 175 of the contact insulating layers 160′ may be in contact with the second gate electrode portion 130b in the horizontal direction (X-direction).

FIG. 5C is an enlarged view illustrating another embodiment of region B of the semiconductor device of FIG. 4.

Among the remaining components except for gate electrodes 130′ illustrated in FIG. 5C, overlapping descriptions of components that are identical to or which correspond to those illustrated in FIG. 5A will be omitted.

A semiconductor device 100b may include the gate electrodes 130′. The gate electrodes 130′ may include a first gate electrode portion 130a′ corresponding to the contact region 130P and connected to the contact plug 170, and a second gate electrode portion 130b′ in contact with the contact insulating layer 160. In an example, the first gate electrode portion 130a′ may include barrier films 133a, a conductive film 131a disposed between the barrier films 133a, and a first air gap ag1 disposed inside the conductive film 131a. The second gate electrode portion 130b′ may include barrier films 133b, a conductive film 131b disposed between the barrier films 133b, and a second air gap ag2 disposed inside the conductive film 131b.

The first air gap ag1 of the first gate electrode portion 130a′ may be in contact with the horizontal extension portion 170H in the horizontal direction (X-direction). The second air gap ag2 of the second gate electrode portion 130b′ may be in contact with the contact insulating layer 160 in the horizontal direction (X-direction).

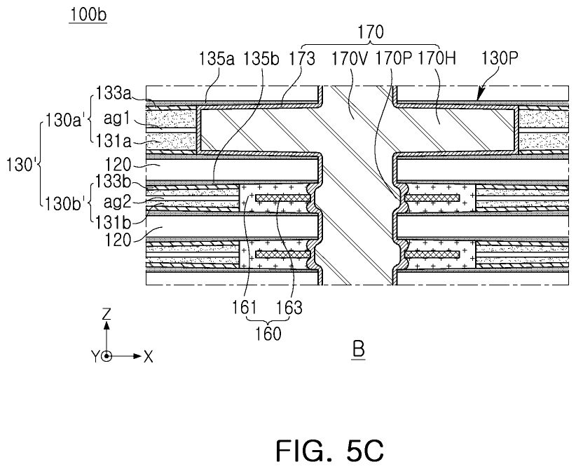

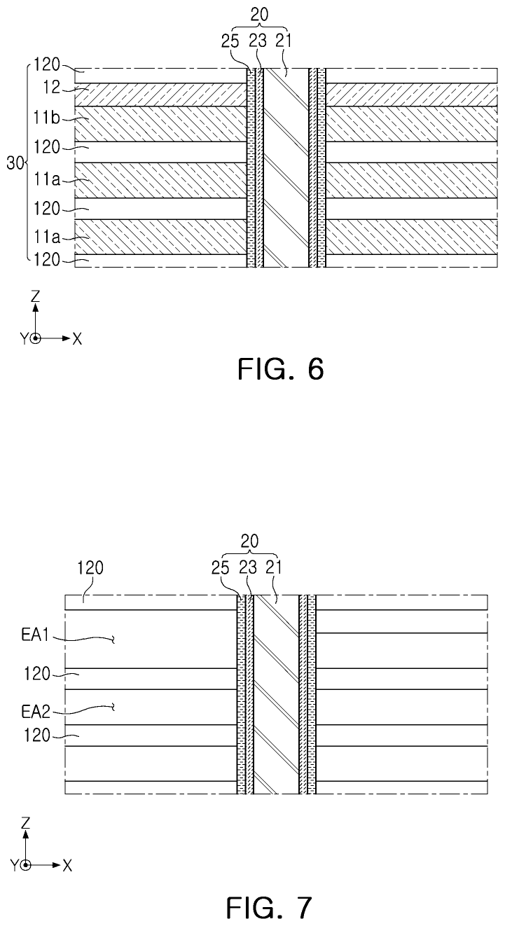

FIGS. 6 to 15 are cross-sectional views illustrating an embodiment of a method of manufacturing the semiconductor device of FIG. 1. Referring to FIGS. 6 to 15, process operations of forming a contact plug 170 connected to a contact region 130P of a gate electrode 130 of a semiconductor device will be described.

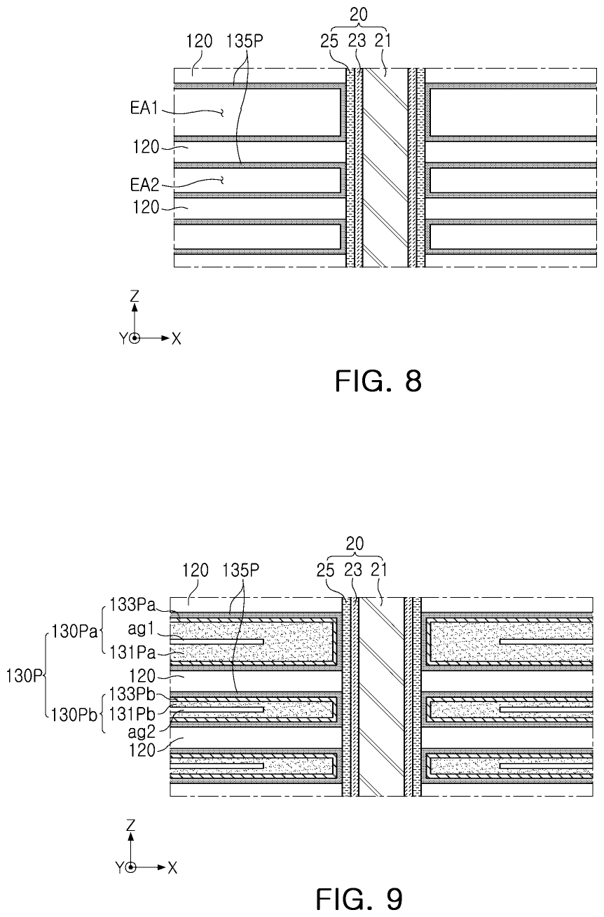

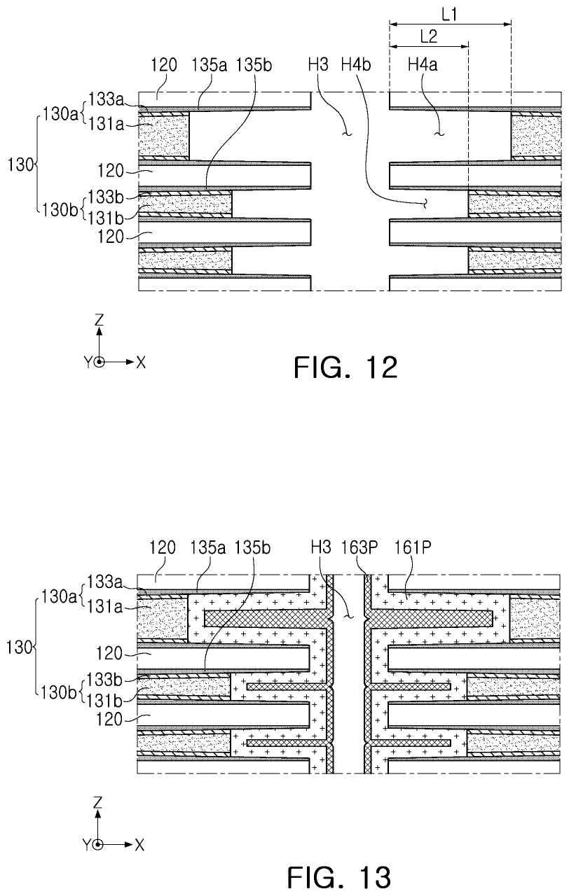

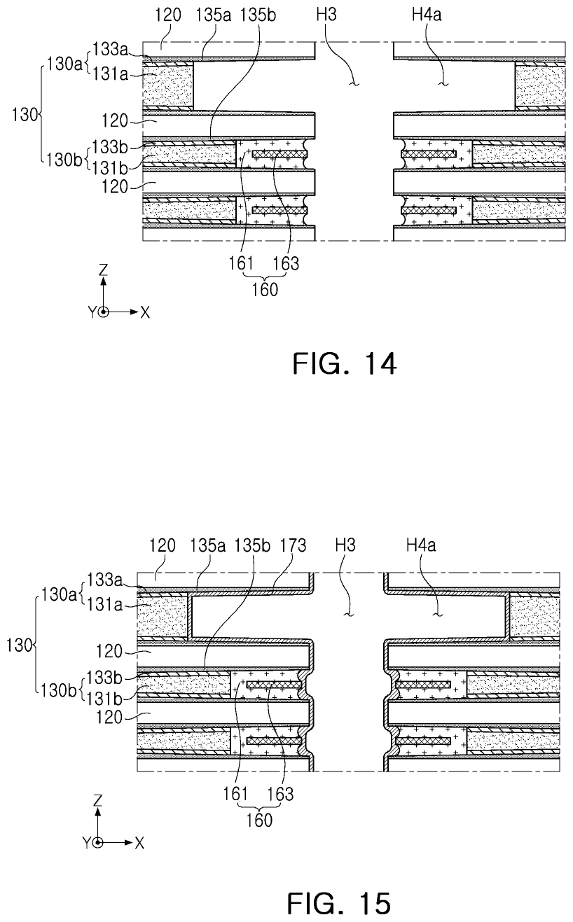

A method of manufacturing a semiconductor device according to example embodiments may include an operation of forming a preliminary stack structure 30 and a sacrificial film structure 20 penetrating through the preliminary stack structure 30 (see FIG. 6), an operation of removing the first and second sacrificial insulating layers 11a, 11b and 12 of the preliminary stack structure 30 to form first and second gap regions EA1 and EA2 (see FIG. 7), an operation of forming a preliminary blocking pattern 135P in the first and second gap regions EA1 and EA2 (see FIG. 8), an operation of forming preliminary gate electrodes 130P on the preliminary blocking pattern 135P in the first and second gap regions EA1 and EA2 (see FIG. 9), an operation of forming a first hole H3 by removing the sacrificial film structure 20, an operation of forming a first extension portion H4a selectively extending inside the first hole H3 in the horizontal direction (X-direction) and having a first length L1 and a second extension portion H4b having a second length L2 smaller than the first length L1 (see FIG. 12), an operation of forming preliminary contact insulating layers 161P and 163P in the first and second extension portions H4a and H4b (see FIG. 13), an operation of removing the preliminary contact insulating layers 161P and 163P in the first extension portion H4a and the first hole H3 (see FIG. 14), and an operation of at least partially filling the first extension portion H4a and the first hole H3 with a metallic material.

Referring to FIG. 6, the preliminary stack structure 30 and the sacrificial film structure 20 penetrating or extending through the preliminary stack structure 30 may be formed.

The preliminary stack structure 30 may include a first sacrificial insulating layer 11a, second sacrificial insulating layers 11b and 12, and an interlayer insulating layer 120. The first sacrificial insulating layer 11a and the interlayer insulating layer 120 may be alternately arranged in the third direction (Z-direction). The second sacrificial insulating layers 11b and 12 may be formed on the interlayer insulating layer 120 disposed on an uppermost first sacrificial insulating layer 11a. In an example, the second sacrificial insulating layers 11b and 12 correspond to a portion of a stepwise region of the preliminary stack structure 30 so that upper surfaces thereof may be at least partially exposed upwardly. In an example, a thickness of the second sacrificial insulating layers 11b and 12 may be thicker than a thickness of the first sacrificial insulating layer 11a in the Z-direction.

The first sacrificial insulating layer 11a and the second sacrificial insulating layers 11b and 12 may be layers that are replaced with gate electrodes (e.g., gate electrodes 130 in FIG. 2) through a subsequent process. The first sacrificial insulating layer 11a and the second sacrificial insulating layers 11b and 12 may be formed to correspond to portions in which gate electrodes are to be formed. The first sacrificial insulating layer 11a may be a layer that is replaced with a second gate electrode portion (e.g., the second gate electrode portion 130b in FIG. 5A). The second sacrificial insulating layers 11b and 12 may be a layer that is replaced with a first gate electrode portion (e.g., the first gate electrode portion 130a in FIG. 5A).

In an example, the first sacrificial insulating layer 11a and the second sacrificial insulating layers 11b and 12 may include a material having etch selectivity with respect to the interlayer insulating layer 120. The first sacrificial insulating layer 11a and the second sacrificial insulating layers 11b and 12 may include an insulating material different from the interlayer insulating layer 120. For example, the interlayer insulating layer 120 may include silicon oxide. The first sacrificial insulating layer 11a and the second sacrificial insulating layers 11b and 12 may include silicon nitride and/or silicon oxynitride.

The second sacrificial insulating layers 11b and 12 may include a second-first sacrificial insulating layer 11b and a second-second sacrificial insulating layer 12 on the second-first sacrificial insulating layer 11b. The second-second sacrificial insulating layer 12 may include an insulating material having etch selectivity higher than that of the second-first sacrificial insulating layer 11b. In an example, a thickness of the second-second sacrificial insulating layer 12 may be less than a thickness of the second-first sacrificial insulating layer 11b in the Z-direction.

The sacrificial film structure 20 may penetrate or extend through the preliminary stack structure 30 in a third direction (Z-direction), a vertical direction. The sacrificial film structure 20 may be replaced with a contact plug (e.g., the contact plug 170 of FIG. 2) through a subsequent process. In an example, the sacrificial film structure 20 may include a first sacrificial film 21, a second sacrificial film 23 surrounding the first sacrificial film 21 in a plan view, and a third sacrificial film 25 surrounding the second sacrificial film 23 in a plan view. In an example, the first sacrificial layer 21 may be thicker than the second and third sacrificial layers 23 and 25. In an example, the sacrificial film structure 20 may include a material that has etch selectivity with respect to the interlayer insulating layer 120. For example, the first sacrificial layer 21 may include carbon (C) and/or polysilicon. The second sacrificial layer 23 may include silicon nitride, and the third sacrificial layer 25 may include silicon oxide.

Referring to FIG. 7, the first and second sacrificial insulating layers 11a, 11b and 12 of the preliminary stack structure 30 may be removed to form first and second gap regions EA1 and EA2. The first and second sacrificial insulating layers 11a, 11b and 12 may be removed in a wet etching process.

The sacrificial film structure 20 may serve to prevent or reduce deformation of the interlayer insulating layer 120 while forming the first and second gap regions EA1 and EA2. Side surfaces of the sacrificial film structure 20 inside the first and second gap regions EA1 and EA2 may be exposed.

Referring to FIG. 8, a preliminary blocking pattern 135P may be formed in the first and second gap regions EA1 and EA2. The preliminary blocking pattern 135P may be formed conformally along a surface profile of an inner wall of the first and second gap regions EA1 and EA2. The preliminary blocking pattern 135P may have a certain thickness. In an example, the preliminary blocking pattern 135P may include metal oxide. For example, the preliminary blocking pattern 135P may include aluminum nitride (AlN), aluminum oxynitride (AlON), aluminum oxide (AlO), and/or aluminum oxide carbide (AlOC).

Referring to FIG. 9, a preliminary gate electrode 130P may be formed on the preliminary blocking pattern 135P in the first and second gap regions EA1 and EA2. In an example, a first preliminary gate electrode portion 130Pa may be formed in the first gap region EA1. A second preliminary gate electrode portion 130Pb may be formed in the second gap region EA2. In an example, forming the preliminary gate electrode 130P may include forming preliminary barrier films 133Pa and 133Pb on the preliminary blocking pattern 135P in the first and second gap regions EA1 and EA2, and forming preliminary conductive films 131Pa and 131Pb on the preliminary barrier film 133Pa and 133Pb. In an example, the preliminary barrier films 133Pa and 133Pb may be formed conformally along a surface profile of the preliminary blocking pattern 135P.

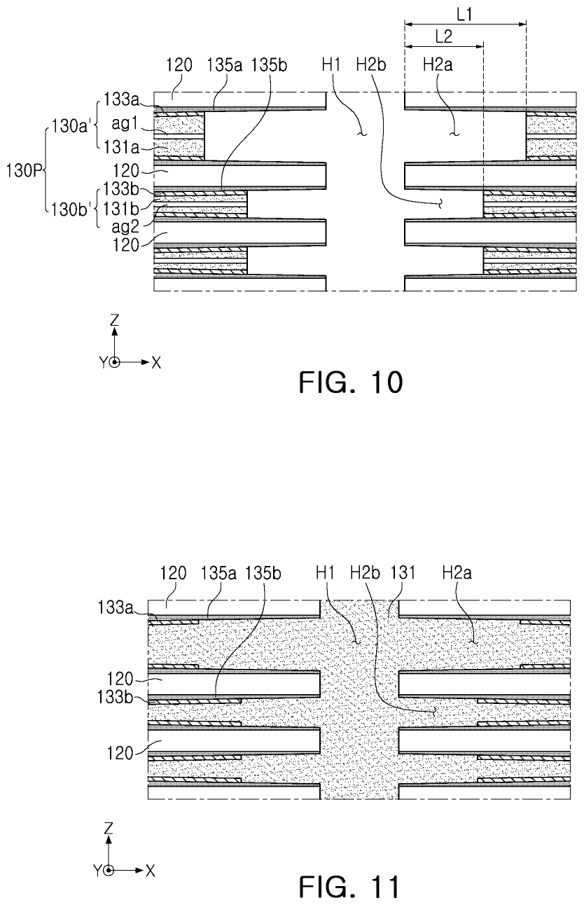

Referring to FIG. 10, the method of manufacturing a semiconductor device according to example embodiments may include an operation of forming preliminary gate electrodes 130P and then forming a preliminary hole H1 by removing the sacrificial film structure 20, and an operation of forming a first preliminary extension portion H2a having a first length L1 by selectively extending in the horizontal direction (X=direction) inside the preliminary hole H1 and a second preliminary extension portion H2b having a second length L2 smaller than the first length L1.

The preliminary hole H1 may be a region in which a vertical extension portion of the contact plug (e.g., the vertical extension portion 170V in FIG. 5A) is formed through a subsequent process. The first preliminary extension portion H2a may be a region in which a horizontal extension portion of the contact plug (e.g., the horizontal extension portion 170H of FIG. 5A) is formed through the subsequent process. The second preliminary extension portion H2b may be a region in which a contact insulating layer (e.g., the contact insulating layer 160 in FIG. 5A) is formed through the subsequent process.

In the operation of forming the first preliminary extension portion H2a, a first gate electrode portion 130a′ may be formed by partially removing the first preliminary gate electrode portion 130Pa in the horizontal direction (X-direction) from the preliminary hole H1. In the operation of forming the second preliminary extension portion H2b, the second gate electrode portion 130b′ may be formed by partially removing the second preliminary gate electrode portion 130Pb from the preliminary hole H1 in the horizontal direction. A thickness of the first preliminary gate electrode portion 130Pa in the third direction (Z-direction) may be thicker than a thickness of the second preliminary gate electrode portion 130Pb in the third direction (Z-direction). That is, an area of the first preliminary gate electrode portion 130Pa in contact with the preliminary hole H1 may be larger than an area of the second preliminary gate electrode portion 130Pb in contact with the preliminary hole H1. In an example, in a process of etching a portion of the first preliminary gate electrode portion 130Pa and the second preliminary gate electrode portion 130Pb from the preliminary hole H1 in the horizontal direction (X-direction), due to a difference in area between the first preliminary gate electrode portion 130Pa and the second preliminary electrode portion 130Pb in contact with the preliminary hole H1, a portion of the first preliminary gate electrode portion 130Pa, etched in the horizontal direction (X-direction), may be larger than a portion of the second preliminary gate electrode portion 130Pb, etched in the horizontal direction.

One side surface of the first gate electrode portion 130a′ and one side surface of the second gate electrode portion 130b′ may be exposed through the first preliminary expansion portion H2a and the second preliminary expansion portion H2b. One cross-section of the barrier films 133a and 133b, the conductive films 131a and 131b, and the first and second air gaps ag1 and ag2 buried in the conductive films 131a and 131b may be exposed.

In the operation of forming the first and second preliminary extension portions H2a and H2b, as the first and second preliminary gate electrode portions 130Pa and 130Pb are partially etched in the preliminary hole H1 in the horizontal direction (X-direction), a portion of the preliminary blocking pattern 135P in contact with the first and second preliminary gate electrode portions 130Pa and 130Pb may also be etched. In an example, the first and second blocking patterns 135a and 135b adjacently to the preliminary hole H1 may be at least partially exposed through the first and second preliminary extension portions H2a and H2b. In an example, a thickness of the first and second blocking patterns 135a and 135b may decrease as the first and second blocking patterns 135a and 135b approach the preliminary hole H1.

Referring to FIG. 11, the method thereof may include an operation of at least partially filling the preliminary hole H1 and the first and second preliminary extension portions H2a and H2b with a conductive material 131. By at least partially filling the first and second preliminary extension portions H2a and H2b with the conductive material 131, the first and second air gaps ag1 and ag2 exposed through the first and second preliminary extension portions H2a and H2b may be at least partially filled with the conductive material 131. Accordingly, the first and second air gaps ag1 and ag2 may be removed. In an example, the conductive material 131 may include the same material as the conductive film 131a and 131b of FIG. 10.

In an example embodiment, a process operation of removing the first and second air gaps ag1 and ag2 by at least partially filling the first and second air gaps ag1 and ag2 with the conductive material 131 may not be performed. The operation of forming the preliminary hole H1 and the first and second extension portions H2a and H2b and the operation of at least partially filling the first and second extension portions H2a and H2b with the conductive material 131 may be omitted. In this case, the operation of forming preliminary contact insulating layers 161P and 163P in the preliminary hole H1 and the first and second preliminary extension portions H2a and H2b may be performed.

Referring to FIG. 12, the conductive material 131 in the preliminary hole H1 may be removed to form a first hole H3. A first extension portion H4a selectively extended in the horizontal direction (X-direction) and having a first length L1 and a second extension portion H4b having a second length L2 smaller than the first length L1 may be formed in the first hole H3.

In the operation of forming the first extension portion H4a, the first gate electrode portion 130a may be formed by removing the conductive material 131 in the first preliminary expansion portion H2a. In the operation of forming the second extension portion H4b, the second gate electrode portion 130b may be formed by removing the conductive material 131 in the second preliminary expansion portion H2b.

Referring to FIGS. 11 and 12, a thickness of the first preliminary expansion portion H2a in the third direction (Z-direction) may be thicker than a thickness of the second preliminary expansion portion H2b in the third direction (Z-direction). An area of the conductive material 131 in the first preliminary extension portion H2a in contact with the preliminary hole H1 may be larger than an area of the conductive material 131 in the second preliminary expansion portion H2b in contact with the preliminary hole H1. In an example, in the process of etching a portion of the conductive material 131 in the first and second preliminary extension portions H2a and H2b in the horizontal direction from the preliminary hole H1, due to a difference between a cross-sectional area of the first preliminary expansion portion H2a in contact with the preliminary hole H1 and a cross-sectional area of the second preliminary expansion portion H2b in contact with the preliminary hole H1, the conductive material 131 in the first preliminary extension portion H2a etched in the horizontal direction may be greater than the conductive material 131 in the second preliminary extension portion H2b etched in the horizontal direction.

Referring to FIG. 13, a first preliminary contact insulating layer 161P and a second preliminary contact insulating layer 163P may be sequentially formed inside the first and second extension portions H4a and H4b.

The first preliminary contact insulating layer 161P may be conformally disposed along a surface profile of an inner wall of the first and second extension portions H4a and H4b. The second preliminary contact insulating layer 163P may be formed on the first preliminary contact insulating layer 161P to reduce the likelihood or prevent an air gap from being formed in the first preliminary contact insulating layer 161P. The second preliminary contact insulating layer 163P may include an insulating material different from that of the first preliminary contact insulating layer 161P. In an example embodiment, an operation of oxidizing the preliminary contact insulating layers 161P and 163P after forming the preliminary contact insulating layers 161P and 163P may be further included.

Referring to FIG. 14, the preliminary contact insulating layers 161P and 163P formed in the first extension portion H4a and the first hole H3 may be removed. The contact insulating layer 160 may be formed by removing the preliminary contact insulating layers 161P and 163P formed in the first extension portion H4a and the first hole H3 through a wet etching process.

As the preliminary contact insulating layers 161P and 163P formed in the first extension portion H4a and the first hole H3 are removed, a side wall of the first hole H3 may be exposed. In an example, in the process of removing the preliminary contact insulating layers 161P and 163P formed in the first hole H3, a portion of the preliminary contact insulating layers 161P and 163P in the second extension portion H4b extending in the horizontal direction (X-direction) of the first hole H3 may be removed. A region recessed from a side surface of the first hole H3 to one surface of the contact insulating layer 160 adjacently to the second extension portion H4b may be included due to the difference in etching rate between the first preliminary contact insulating layer 161P and the second preliminary contact insulating layer 163P, and one surface of the contact insulating layer 160 having a concavo-convex structure may be at least partially exposed. In an example, an etching rate of the first preliminary contact insulating layer 161P may be greater than an etching rate of the second preliminary contact insulating layer 163P.

Referring to FIG. 15, a barrier film 173 may be formed on a surface of the first hole H3 expending from an internal surface of the first extension portion H4a and an internal surface of the first extension portion H4a. The barrier film 173 may be formed conformally along a surface profile in the first extension portion H4a and a side surface of the first hole H3.

Next, referring to FIG. 5A, the contact plug 170 may be formed by depositing a conductive material in the first extension portion H4a and the first hole H3.

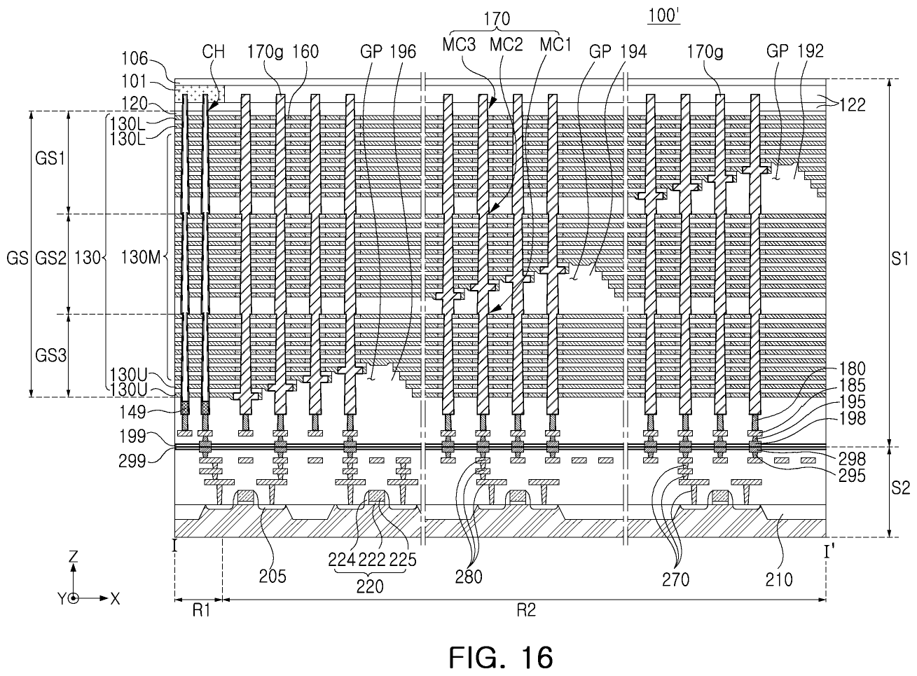

FIG. 16 is a cross-sectional view taken along line I-I′ of the semiconductor device of FIG. 1 according to another example embodiment.

Referring to FIG. 16, a semiconductor device 100′ may include a memory cell structure S1 and a peripheral circuit structure S2 bonded using a wafer bonding method.

The description of the peripheral circuit region PERI described above with reference to FIG. 2 may be applied to the peripheral circuit structure S2, the first semiconductor structure. However, the peripheral circuit structure S2 may further include second bonding vias 295, second bonding metal layers 298, and a second bonding insulating layer 299, which are included in a bonding structure. The second bonding vias 295 may be electrically connected to lines 280 in an uppermost portion. At least a portion of the second bonding metal layer 298 may be connected to the second bonding vias 295. The second bonding metal layer 298 may be connected to the first bonding metal layers 198 of the memory cell structure S1. The second bonding metal layers 298 and the first bonding metal layers 198 may provide an electrical connection path for bonding the memory cell structure S1 and the peripheral circuit structure S2. In another example, some of the second bonding metal layers 298 may not be electrically connected to lines 280 in a lower portion and may be disposed only for bonding.

The second bonding vias 295 and the second bonding metal layers 298 may include a conductive material, for example, copper (Cu). The second bonding insulating layer 299 may be disposed around the second bonding metal layers 298. The second bonding insulating layer 299 may also function as a diffusion barrier for the second bonding metal layers 298, and may include, for example, SiN, SiON, SiCN, SiOC, SiOCN, and/or SiO.

Where there is no other description of the memory cell structure S1, the second semiconductor structure, the description of the memory cell region CELL described above with reference to FIG. 2 may be applied. The memory cell structure S1 may further include a substrate insulating layer 122, cell interconnection lines 185, and first bonding vias 195, first bonding metal layers 198 and a first bonding insulating layer 199, which are included in the bonding structure. In an example, the memory cell structure S1 may further include a passivation layer 106 on and at least partially covering an upper surface of the plate layer 101 and an upper surface of the substrate insulating layers 121.

The substrate insulating layer 122 may be disposed below (in the Z-direction) the gate structure GS, may be disposed between the plate layer 101 and the gate structure GS on the first region R1, and may be disposed on the same level (in the Z-direction) as the plate layer 101 in the second region R2. The channel structure CH may be disposed inside the plate layer 101 by penetrating or extending through the gate structure GS and the substrate insulating layer 122 in the first region R1.

The substrate insulating layer 122 may be disposed on the plate layer 101 in the first region R1 and may be disposed on the same level (in the Z-direction) as the plate layer 101 in the second region R2.

The cell interconnection lines 185 may be electrically connected to the studs 180. However, in example embodiments, the number of layers and arrangement forms of plugs and interconnection lines included in the cell interconnection structure may be variously changed. The cell interconnection lines 185 may be formed of a conductive material and may include, for example, tungsten (W), aluminum (Al), and/or copper (Cu).

The first bonding vias 195 and first bonding metal layers 198 may be disposed below (in the Z-direction) the cell interconnection lines 185 in a lowermost portion. The first bonding vias 195 may connect the cell interconnection lines 185 and the first bonding metal layers 198, and the first bonding metal layers 198 may be bonded to the second bonding metal layers 298 of the peripheral circuit structure S2. The first bonding insulating layer 199 may be bonded and connected to the second bonding insulating layer 299 of the peripheral circuit structure S2. The first bonding vias 195 and the first bonding metal layers 198 may include a conductive material, such as copper (Cu). The first bonding insulating layer 199 may include, for example, SiO, SiN, SiCN, SiOC, SiON, and/or SiOCN.

The memory cell structure S1 and the peripheral circuit structure S2 may be bonded by bonding the first bonding metal layers 198 and the second bonding metal layers 298 and bonding the first bonding insulating layer 199 and the second bonding insulating layer 299. The bonding of the first bonding metal layers 198 and the second bonding metal layers 298 may be, for example, copper (Cu)-copper (Cu) bonding, and the bonding of the first bonding insulating layer 199 and the second bonding insulating layer 299 may be, for example, dielectric-dielectric bonding such as SiCN-SiCN bonding. The memory cell structure S1 and the peripheral circuit structure S2 may be bonded by hybrid bonding including copper (Cu)-copper (Cu) bonding and dielectric-dielectric bonding.

The passivation layer 106 may be disposed on the upper surface of the plate layer 101 and may protect the semiconductor device 10d. The passivation layer 106 may include at one or more insulating materials, for example, silicon oxide, silicon nitride, and/or silicon carbide. The substrate insulating layer 121 may be widely disposed in the first region R1 and the second region R2 so as to cover an upper end of the contact plugs 170, an upper end of a through-plug 164, and an upper end of the capacitor contacts 165. However, in example embodiments, the arrangement of the substrate insulating layer 121 may be variously changed, within a range in which the contact plugs 170, the through-plug 164 and the capacitor contacts 165 are electrically separated from the plate layer 101.

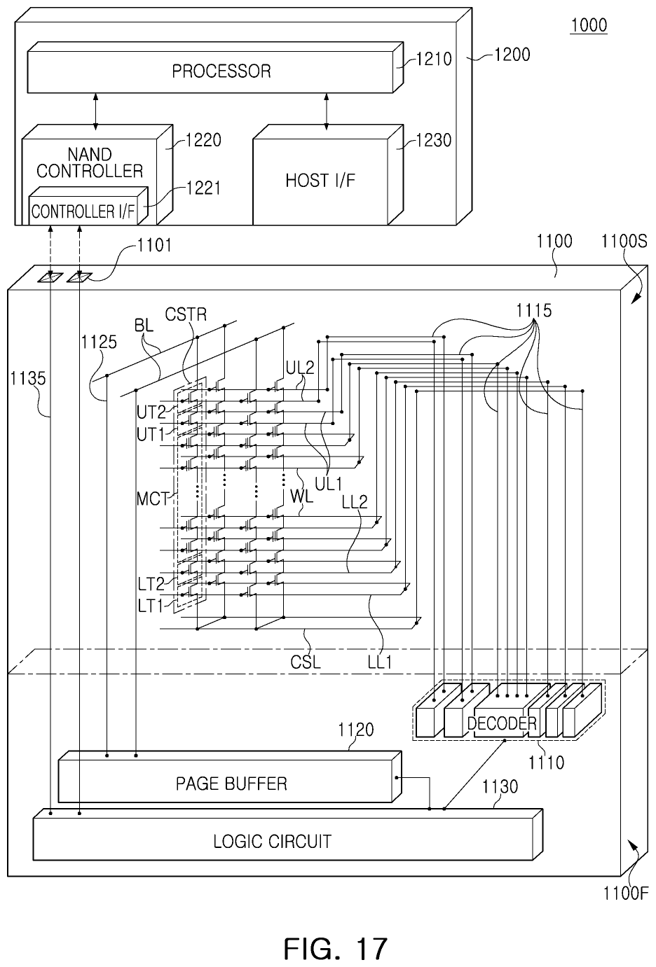

FIG. 17 is a view schematically illustrating a data storage system including a semiconductor device according to example embodiments of the present disclosure.

Referring to FIG. 17, a data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD) device, a universal serial bus (USB) device, a computing system, a medical device, or a communication device including one or a plurality of semiconductor devices 1100.

The semiconductor device 1100 may be a non-volatile memory device, and may be, for example, the NAND flash memory device described above with reference to FIGS. 1 to 3. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacently to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example embodiments.

In example embodiments, the upper transistors UT1 and UT2 may include string select transistors, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground selection transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used in an erase operation of deleting data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 1100F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pad 1101 may be electrically connected to the logic circuit 1130 through an input/output connection interconnection 1135 extending from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000, including the controller 1200. The processor 1210 may operate according to predetermined firmware, and may control the NAND controller 1220 to access the semiconductor device 1100. The NAND controller 1220 may include a controller interface 1221 configured to process communication with the semiconductor device 1100. Through the controller interface 1221, control commands for controlling the semiconductor device 1100, data to be recorded in the memory cell transistors MCT of the semiconductor device 1100 and data to be read from the memory cell transistors MCT of the semiconductor device 1100 may be transmitted. The host interface 1230 may provide a communication function between the data storage system 1000 and an external host. When receiving the control commands from the external host through the host interface 1230, the processor 1210 may control the semiconductor device 1100 in response to the control commands.

While example embodiments have been illustrated and described above, it will be apparent to those skilled in the art that modifications and variations could be made within a scope not departing from the spirit and region of the present disclosure as defined by the appended claims.

What is claimed is:

1. A semiconductor device, comprising:
a first semiconductor structure including a substrate, circuit elements on the substrate, and circuit interconnections on the circuit elements; and
a second semiconductor structure on the first semiconductor structure and having first and second regions,
wherein the second semiconductor structure includes:
a plate layer;
gate electrodes stacked on the plate layer and spaced apart from each other in a direction, perpendicular to an upper surface of the plate layer, and extending by different lengths in a first direction, intersecting the perpendicular direction, on the second region, each of which includes a pad region in which an upper surface thereof is at least partially exposed;
interlayer insulating layers alternately arranged with the gate electrodes;
a channel structure extending through the gate electrodes and the interlayer insulating layers in the first region and extending in the perpendicular direction; and
contact plugs extending through the pad region of each of the gate electrodes in the second region, extending in the perpendicular direction, and electrically connecting the gate electrodes to a portion of the circuit interconnections, respectively; and
contact insulating layers alternately arranged with the interlayer insulating layers in a lower portion of each of pad regions and configured to surround the contact plugs in a plan view of the semiconductor device,
wherein each of the contact plugs includes a vertical extension portion extending in the perpendicular direction and a horizontal extension portion extending from the vertical extension portion in the first direction and contacting the pad portion, and
wherein a width of the horizontal extension portion of the contact plugs in the first direction is greater than a width of each of the contact insulating layers in the first direction.

2. The semiconductor device of claim 1, further comprising:
first blocking patterns between the horizontal extension portion and the interlayer insulating layers; and
second blocking patterns between the contact insulating layers and the interlayer insulating layers.

3. The semiconductor device of claim 2, wherein a thickness of each of the first blocking patterns and a thickness of each of the second blocking patterns decrease in the perpendicular direction as the first blocking patterns and the second blocking patterns approach the vertical extension portion.

4. The semiconductor device of claim 2, wherein the gate electrodes correspond to the pad region and include a first gate electrode portion in contact with the horizontal extension portion and a second gate electrode portion in contact with the contact insulating layer, and
a thickness of the first gate electrode portion is thicker than a thickness of the second gate electrode portion in the perpendicular direction.

5. The semiconductor device of claim 4, wherein the first blocking patterns extend between the first gate electrode portion and the interlayer insulating layers, and
wherein the second blocking patterns extend between the second gate electrode portion and the interlayer insulating layers.

6. The semiconductor device of claim 4, wherein the first gate electrode portion includes a first air gap,
wherein the second gate electrode portion includes a second air gap,
wherein the first air gap is in contact with the horizontal extension portion, and
wherein the second air gap is in contact with the contact insulating layers.

7. The semiconductor device of claim 2, wherein the first blocking patterns and the second blocking patterns include metal oxide.

8. The semiconductor device of claim 1, wherein a portion of the horizontal extension portion does not overlap the contact insulating layers in the perpendicular direction.

9. The semiconductor device of claim 1, wherein each of the contact insulating layers includes a first insulating pattern including a first insulating material, and a second insulating pattern including a second insulating material different from the first insulating material and on an internal surface of the first insulating pattern.

10. The semiconductor device of claim 9, wherein each of the contact insulating layers further includes an insulating liner including a third insulating material different from the first insulating material and on an outer surface of the first insulating pattern.

11. The semiconductor device of claim 10, wherein the third insulating material and the second insulating material are a same material.

12. The semiconductor device of claim 9, wherein each of the contact plugs further includes a protrusion portion protruding from the vertical extension portion to the contact insulating layers in the first direction.

13. The semiconductor device of claim 12, wherein one surface of the protrusion portion in contact with the first insulating pattern and the second insulating pattern has a concavo-convex structure.

14. A semiconductor device comprising:
a stack pattern having a memory cell array region and a stepwise region;
a stack structure extending from the memory cell array region onto the stepwise region on the stack pattern, wherein the stack structure includes interlayer insulating layers and gate electrodes arranged alternately in a first direction, and the gate electrodes include gate pads arranged in a stepwise shape on the stepwise region,
a channel structure extending through the stack structure in the memory cell array region and extending in the first direction;
contact plugs extending through the gate electrodes and the interlayer insulating layers in the stepwise region; and
contact insulating layers arranged alternately with the interlayer insulating layers between the gate pads and the stack pattern and configured to surround the contact plugs in a plan view of the semiconductor device,
wherein each of the contact plugs includes a vertical extension portion extending in the first direction and a horizontal extension portion extending in a second direction from the vertical extension portion perpendicular to the first direction and contacting the gate pads, and
wherein the semiconductor device further includes first blocking patterns extending from a space between the gate pads and the interlayer insulating layers to a space between the horizontal extension portion and the interlayer insulating layers.

15. The semiconductor device of claim 14, wherein a thickness of each of the first blocking patterns decreases in the first direction as the first blocking patterns approach the vertical extension portion.

16. The semiconductor device of claim 14, wherein the gate electrodes that are between the gate pads and the stack pattern are in contact with the contact insulating layers in the second direction, and
wherein the semiconductor device further includes second blocking patterns extending from a space between the gate electrodes that are between the gate pads and the stack pattern and the interlayer insulating layers to a space between the contact insulating layers and the interlayer insulating layers.

17. The semiconductor device of claim 16, wherein a distance between the first blocking patterns is greater than a distance between the second blocking patterns in the first direction.

18. The semiconductor device of claim 13, wherein a width of the horizontal extension portion in the second direction is greater than a width of each of the contact insulating layers in the second direction.

19. A data storage system, comprising:
a semiconductor storage device including a first semiconductor structure including circuit elements and circuit interconnections electrically connected to the circuit elements, a second semiconductor structure on one surface of the first semiconductor structure and including a first region and a second region, and an input/output pad electrically connected to the circuit elements; and
a controller electrically connected to the semiconductor storage device through the input/output pad and configured to control the semiconductor storage device,
wherein the second semiconductor structure includes:
a plate layer;
gate electrodes stacked on the plate layer and spaced apart from each other in a direction, perpendicular to an upper surface of the plate layer, and extending by different lengths in a first direction, intersecting the perpendicular direction, on the second region, each of which includes a pad region in which an upper surface thereof is at least partially exposed;
interlayer insulating layers alternately arranged with the gate electrodes;
a channel structure extending through the gate electrodes and the interlayer insulating layers in the first region and extending in the perpendicular direction;
contact plugs extending through the pad region of each of the gate electrodes in the second region, extending in the perpendicular direction, and electrically connecting the gate electrodes to a portion of the circuit interconnections, respectively; and
contact insulating layers alternately arranged with the interlayer insulating layers in a lower portion of each of pad regions and configured to surround the contact plugs in a plan view of the semiconductor storage device,
wherein each of the contact plugs includes a vertical extension portion extending in the perpendicular direction and a horizontal extension portion extending from the vertical extension portion in the first direction and contacting the pad region, and
wherein first blocking patterns are between the horizontal extension portion and the interlayer insulating layers, and second blocking patterns are between the contact insulating layers and the interlayer insulating layers.

20. The data storage system of claim 19, wherein a thickness of each of the first blocking patterns and a thickness of each of the second blocking patterns decrease in the perpendicular direction as the first blocking patterns and the second blocking patterns approach the vertical extension portion.
